(19) United States
(12) Patent Application Publication
(10) Pub. No.: US 2026/0102872 A1
(43) Pub. Date: Apr. 16, 2026

(54) METHOD AND SYSTEM FOR PERFORMING CHEMICAL MECHANICAL POLISHING

(71) Applicant: TAIWAN SEMICONDUCTOR MANUFACTURING COMPANY, LTD., Hsinchu (TW)

(72) Inventors: Jui Yu PAI, Hsinchu (TW); Chen-Hsueh LIN, Kaohsiung (TW); Tang-Kuei CHANG, Tainan (TW); Hsun-Hao HSU, Hsinchu (TW)

(21) Appl. No.: 18/912,754

(22) Filed: Oct. 11, 2024

(51) Int. Cl. B24B 37/32; H01L 21/306

(52) U.S. Cl. CPC B24B 37/32; H10P 52/402

(57) ABSTRACT

Embodiments of the present disclosure provide a method and apparatus for polishing a substrate including pre-heating the polishing slurry in-situ. Particularly, the polishing slurry is preheated by a heating element attached to the retaining ring or by rotating the retaining ring relative to the substrate being processed. Pre-heating the slurry on the polishing pad improves polishing uniformity across the substrate by preventing the edge of the substrate being inadvertently cooled by the fresh slurry. Embodiments of the present disclosure further include a retaining ring with a tapered slurry channel, which reduces the decrease of flow area as the retaining ring worn down.

### BACKGROUND

Integrated circuits may be formed using various photolithographic techniques. Such techniques typically include use of a Chemical Mechanical Polishing (CMP) process, which is performed to polish a surface of a substrate. However, conventional CMP processes may have substrate scratch issues, which can lead to substrate acceptance test failure or low substrate yields.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic perspective view of a CMP tool according to embodiments of the present disclosure.

FIG. 1B is a schematic plan view of the CMP tool of FIG. 1A.

FIG. 2 is a schematic cross-sectional view of a carrier head over a polishing pad in accordance with some embodiments.

FIGS. 3A-3B schematically illustrate a retaining ring according to embodiments of the present disclosure.

FIGS. 4A-4B schematically illustrate a retaining ring according to embodiments of the present disclosure.

FIGS. 5A-5B schematically illustrate a retaining ring according to embodiments of the present disclosure.

FIGS. 6A-6B schematically illustrate a retaining ring according to embodiments of the present disclosure.

FIGS. 7A, 7B, 7C, 7D, 7E and 7F schematically illustrate various retaining rings according to embodiments of the present disclosure.

FIGS. 8A-8B schematically illustrate a carrier head with independently rotating retaining ring according to embodiments of the present disclosure.

FIGS. 9A, 9B, 9C, and 9D schematically illustrate a retaining ring according to embodiments of the present disclosure.

FIG. 9E is a chart showing lifetime improvement of the retaining ring according to the present disclosure.

FIG. 10 schematically illustrates a retaining ring according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Chemical Mechanical Polishing (CMP) tool is provided in accordance with various exemplary embodiments. The variations of some embodiments are discussed. Throughout the various views and illustrative embodiments, like reference numbers are used to designate like elements. The embodiments of the present disclosure also include the scope of using the CMP tool in accordance with the embodiments to manufacture integrated circuits. For Example, the CMP tool is used to planarize substrates, in which integrated circuits are formed.

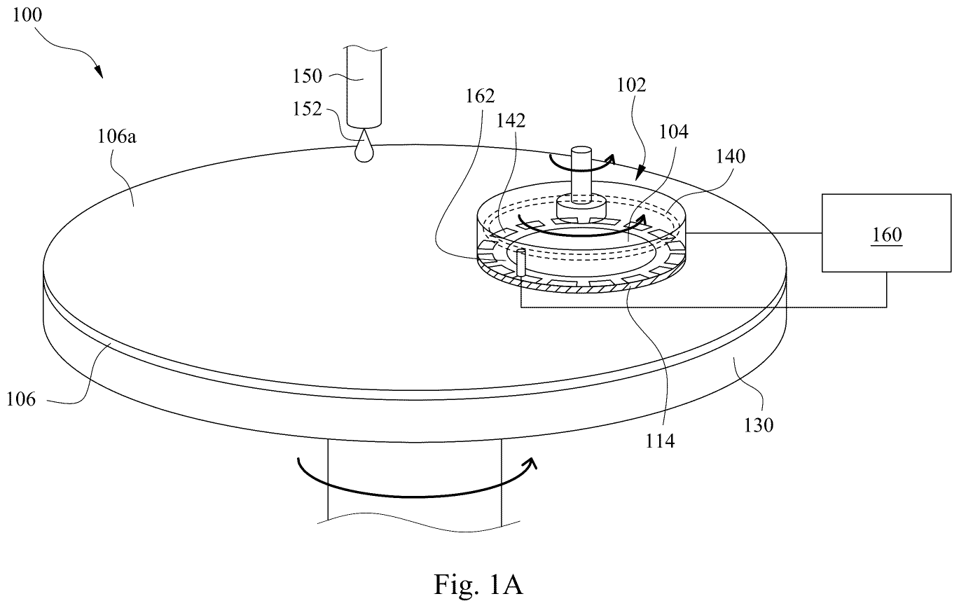

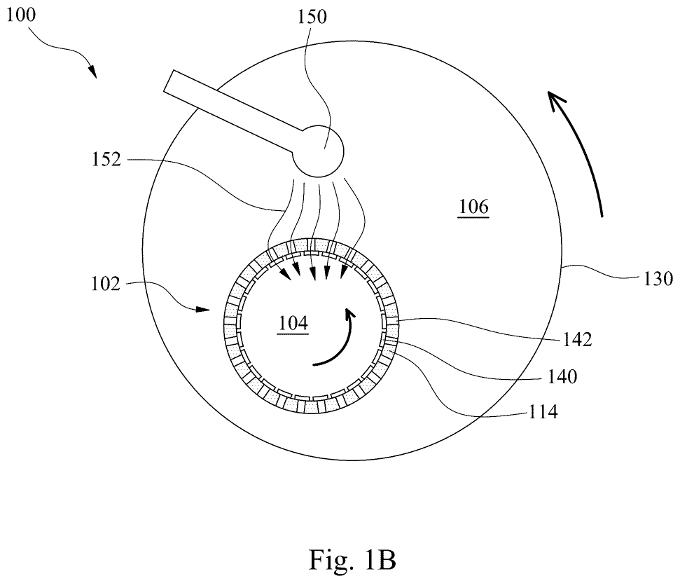

FIG. 1A is a schematic perspective view of a CMP tool 100 according to embodiments of the present disclosure. FIG. 1B is a schematic plan view of the CMP tool 100. The CMP tool 100 may be used as polishing stations in a CMP system. For example, two or more CMP tools 100 may be included in a CMP system to perform a polishing step.

The CMP tool 100 includes a platen 130, a polishing pad 106 disposed over the platen 130, a carrier head 102 disposed over the polishing pad 106. The to-be-polished substrate 104 is placed against a polishing surface 106a of the polishing pad 106 by the carrier head 102. The carrier head 102 includes a retaining ring 114 configured to reduce lateral movement of the substrate 104 with respect to the carrier head 102 during the polishing process. During operation, both the platen 130 and the carrier head 102 may rotate independently to generate relative movement between the polishing pad 106 and the substrate 104 to facilitate polishing.

A slurry dispenser 150 may be disposed on over the polishing pad 106 to dispense a slurry 152 during operation. The slurry 152 includes a reactive chemical solution that reacts with the surface layer of the substrate 104 to assist and/or control polishing. The slurry 152 may include a chemical solution, such as surfactant or wetting agent, and a plurality of abrasive particles in the chemical solution. Furthermore, the slurry 152 may include abrasive particles, e.g., abrasive particles 118, for mechanically polishing the substrate 104.

As shown in FIGS. 1A and 1B, the slurry 152 is dispensed onto a location on the polishing pad 106 outside the area covered by the carrier head 102. The slurry 152 is then flow toward the substrate 104 as the polishing pad 106 and the carrier head 102 rotate during polishing. In some embodiments, the retaining ring 114 may include a plurality of slurry channels 142 formed on a bottom surface facing the polishing pad 106. The plurality of slurry channels 142 form flow paths for the slurry 152.

During polishing, the friction between the substrate 104 and the polishing pad 106 generates heat resulting in temperature increase on the substrate 104. In some embodiments, temperature of the substrate 104 may be in a range between about 20° C. and 58° C. Particularly, temperature of the substrate 104 may raise from room temperature to about 58° C. It has been observed that the material removal rate of the polishing process correlates to the temperature of the substrate. For example, a higher substrate temperature may result in a higher removal rate.

In some embodiments, the fresh slurry 152 may be in a temperature range between about 20° C. and 25° C. The temperature of the fresh slurry 152 may be selected to ensure stability of chemicals and additives prior to operation. Therefore, during polishing process, the temperature of the substrate 104 may be higher than the temperature of the fresh slurry 152. As shown in FIG. 1B, fresh slurry 152 first contacts an edge region of the substrate 104 during polishing. The lower temperature of the fresh slurry 152 may cause the temperature at the edge region of the substrate 104 to drop below the temperature of the center region of the substrate 104. The non-uniformity in the temperature of the substrate 104 may result in non-uniformity of material removal rate.

In some embodiments, the retaining ring 114 may include a heating element 140 configured to pre-heat the fresh slurry 152 prior to contacting the substrate 104. In some embodiments, the heating element 140 includes one or more thermo-electric modules attached to inside and/or outside the retaining ring 114. Alternatively, the heating element may be any suitable device, such as heating coil, to create temperature differences. In some embodiments, the heating element 140 may be used to adjust the temperature of the slurry 152 in a range between about 20° C. and about 100° C.

The CMP tool 100 may further include a controller 160. The heating element 140 may be connected to the controller 160. The controller 160 may selectively activate the heating element 140 to achieve desired temperature around the substrate 104. In some embodiments, the CMP tool 100 may include one or more temperature sensors 162 configurated to measure temperature of the substrate 104 during processing. The temperature sensor 162 may be connected to the controller 160. The controller 160 may use the sensors 162 to detect temperatures around the substrate 104 and send control signals to the hearting element 140 according to the measured temperatures.

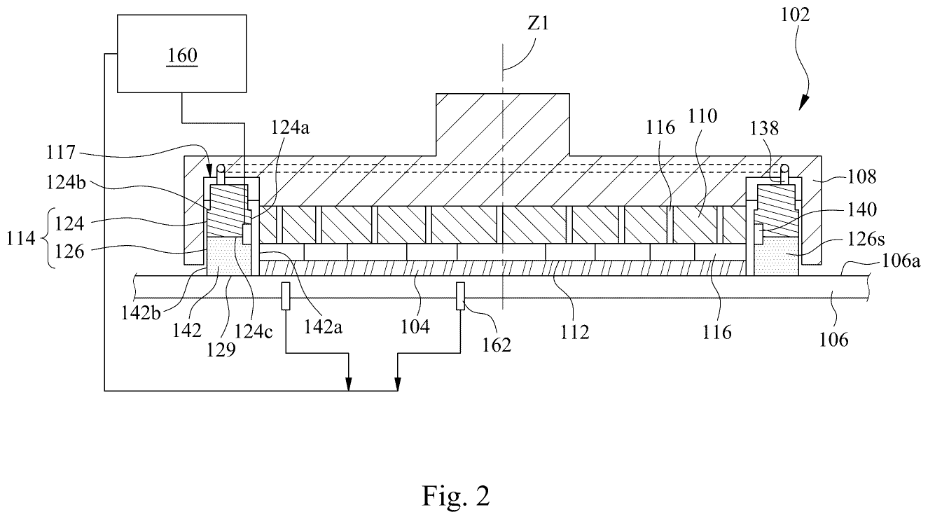

FIG. 2 is a cross-sectional view of the carrier head 102 according to embodiments of the present disclosure. FIG. 2 includes a portion of the polishing pad. The carrier head 102 is usable in a polishing system, such as a CMP tool 100 in FIGS. 1A and 1B. The substrate 104 is secured in the carrier head 102 and between the carrier head 102 and the polishing pad 106. In some embodiments, the substrate 104 contains active devices. In some embodiments, the substrate 104 contains passive devices. In some embodiments, the substrate 104 is a raw un-processed substrate. In some embodiments, the carrier head 102 is configured to move the substrate 104 relative to the polishing pad 106.

The carrier head 102 includes a housing 108, a membrane support 110, a membrane 112, and the retaining ring 114. The housing 108 encloses the membrane support 110 and the substrate 104 and holds the substrate 104 against the polishing pad 106. In some embodiments, the housing 108 is operable of moving in a direction perpendicular to the polishing surface 106a of polishing pad 106 during the polishing process.

The membrane support 110 has one or more ports defined therein. In some embodiments, the membrane support 110 is solid. In some embodiments, the membrane support 110 is a substantially rigid material, such as a metal, a dielectric material, or another suitable material. The membrane 112 is secured to the membrane support 110 and is configured to press the substrate 104 against the polishing pad 106. The membrane 112 has a lower surface configured to be in contact with the substrate 104. In some embodiments, the membrane 112 and the membrane support 110 form one or more chambers 116. The membrane 112 is used to increase uniformity of the pressure applied to the substrate 104 during the polishing process. Pressures of the chambers 116 are set by fluid or air provided through corresponding ports in order to shape or maintain a predetermined surface profile at the lower surface of the membrane 112. As a result, pressure applied to the substrate 104 is controlled to be evenly distributed throughout the entire substrate 104. In some embodiments, the membrane 112 is formed of a flexible and elastic fluid-impermeable material. In some embodiments, the membrane 112 includes at least one of neoprene, chloroprene, ethylene propylene rubber, silicone, or other suitable flexible materials. In some embodiments, the membrane support 110 is omitted, and the housing 108 directly provides support for the membrane 112.

The housing 108 includes a material having sufficient mechanical strength to withstand the pressure exerted during the polishing process. The housing 108 has a diameter sufficiently large to enclose the substrate 104 and the retaining ring 114 surrounding the substrate 104. In some embodiments, the housing 108 includes a retaining ring recess 117 in a periphery region of the housing 108 to accommodate the retaining ring 114. The retaining ring 114 is positioned in the retaining ring recess 117. In some embodiments, the housing 108 is rotatable in a plane parallel to the polishing surface 106a of the polishing pad 106. In some embodiments, the housing 108 is pivotable about an axis Z1 perpendicular to the polishing surface 106a of the polishing pad 106.

In some embodiments, the carrier head 102 further includes one or more cushion members 138 disposed in the retaining ring recess 117. The one or more cushion members 138 are configured to press the retaining ring 114 against the polishing pad 106 and to adjust position of the retaining ring 114 by adjusting corresponding pressures of the cushion members 138. In some embodiments, the cushion members 138 each include a flexible element enclosing the chamber 116 for containing a fluid. In some embodiments, the cushion members 138 include a flexible solid material. In some embodiments, the cushion members 138 are omitted, and the retaining ring 114 is directly attached to the retaining ring recess 117.

The polishing pad 106 is used to remove materials from the substrate 104. In some embodiments, during a polishing process, the retaining ring 114 and the substrate 104 are in contact with the polishing pad 106. In some embodiments, a slurry, such as the slurry 152 shown in FIG. 1B, is dispensed on the polishing pad 106 during the polishing process.

In some embodiments, the polishing pad 106 is movable relative to the substrate 104. In some embodiments, the polishing surface 106a of the polishing pad 106 is a grooved surface and includes grooves, whereby the grooved surface is configured to face a to-be polished surface of the substrate 104. Such a grooved surface may advantageously provide a variety of functions such as, for example, preventing a hydroplaning effect between the polishing pad 106 and the substrate 104, acting as drain channels for removing polishing debris, and ensuring dispensed slurry to be uniformly distributed across the polishing pad 106.

The retaining ring 114 is configured to reduce lateral movement of the substrate 104 with respect to the carrier head 102 during the polishing process. The retaining ring 114 includes a main body portion 124 and a bottom portion 126 connected to the main body portion 124. In some embodiments, the main body portion 124 has a continuous annular shape. The retaining ring 114 is attached to the retaining ring recess 117 through the main body portion 124 of the retaining ring 114. The main body portion 124 includes an inner periphery 124a configured to surround the substrate 104, an outer periphery 124b, and a bottom surface 124c connecting the inner periphery 124a and the outer periphery 124b. The bottom portion 126 is attached to the bottom surface 124c of the main body portion 124.

In some embodiments, the bottom portion 126 may include a plurality of sections 126s separated by the plurality of slurry channels 142 to allow the passage of slurry therethrough. Each of the slurry channels 142 has an inner opening 142a at the inner periphery 124a and an outer opening 142b at the outer periphery 124b. The slurry channels 142 connects the inner periphery 124a and the outer periphery 124b. Each section 126s of the bottom portion 126 has a bottom surface 129 in contact with the polishing pad 106. In some embodiments, micro-grooves may be formed using an ultra-precision machining method, for example, a method using a laser processing apparatus or a superfine processing machine. In some embodiments, the main body portion 124 and the bottom portion 126 of the retaining ring 114 include substantially the same material, for example, non-diamond material, such as high strength thermosetting polymer (e.g., poly-ether ketone (PEEK), polyaryletherketone (PAEK), polytetrafluoroethylene (PTFE), polyphenylene sulfide (PPS), etc.), metal, ceramic, the like, or combinations thereof.

In some embodiments, the heating element 140 is attached to the retaining ring 114 and configured to pre-heat the slurry near the edge region of the substrate 104. After pre-heating, the low temperature fresh slurry would not inadvertently cool down the edge region of the substrate 104, therefore, reducing process non-uniformity across the substrate 104. The heating element 140 may include one or more segments attached along periphery of the retaining ring 114. For example, the heating element 140 may be disposed in along the inner periphery 124a of the retaining ring 114, as shown in FIG. 2. Alternatively, the heating element 140 may be disposed along the outer periphery 124b of the retaining ring 114, or other surfaces of the slurry channels 142.

In some embodiments, the heating element 140 may include one or more segments to be controlled uniformly. In other embodiments, the heating element 140 may include one or more multiple segments and can be individually controlled, therefore, adjust heating effect azimuthally.

In some embodiments, one or mor sensors 162 may be disposed in ports of polishing pad 106. The sensors 162 may be positioned at suitable locations to measure the temperature of the substrate 104 at various radii. For example, a first temperature sensor 162 may be disposed near the edge region of the carrier head 102, or near the retaining ring 114, and a second temperature sensor 162 may be disposed near the center region of the carrier head 102. In some embodiments, measurements of the sensors 162 at edge region and the center region may be compared to control the heating element 140.

The retaining ring 114 with heating elements, and polishing tools with the retaining ring 114 may be used to pre-heat slurry of any types of slurry used for any CMP processes, such as polishing shallow trench isolation (STI), interlayer dielectric (ILD), metal layers, such as copper and tungsten.

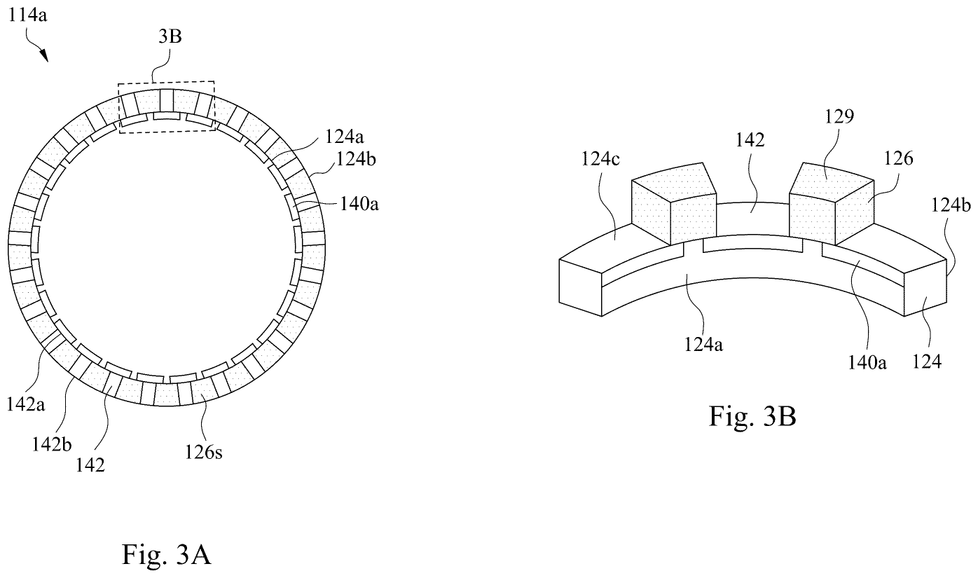

FIG. 3A is a schematic to view of a retaining ring 114a according to embodiments of the present disclosure. FIG. 3B is a partial perspective view of the retaining ring 114a in area 3B in FIG. 3A. The retaining ring 114a may be used as a retaining ring in a carrier head in a polishing station, such as the polishing station 100 of FIG. 1.

The retaining ring 114a includes a main body portion 124. In some embodiments, the main body portion 124 has a closed ring shape. A plurality of bottom sections 126s extending from a bottom surface 124c of the main body portion 124. The bottom sections 126s may be evenly distributed along a periphery of the main body portion 124. A plurality of slurry channels 142 are formed between the bottom sections 126s. In some embodiments, the main body portion 124 and the bottom sections 126s may be formed from non-diamond material, such as high strength thermosetting polymer (e.g., poly-ether ketone (PEEK), polyaryletherketone (PAEK), polytetrafluoroethylene (PTFE), polyphenylene sulfide (PPS), etc.), metal, ceramic, the like, or combinations thereof.

In some embodiments, the bottom sections 126s and the main body portion 124 may be formed from the same material and fabricated from machining the slurry channels 142. In other embodiments, the bottom sections 126s and the main body portion 124 may be formed from different materials.

In some embodiments, the retaining ring 114a includes a plurality of heaters 140a. The heaters 140a are disposed along the inner periphery 124a of the main body portion 124. In some embodiments, each heater 140a may be an elongated element disposed close to the bottom surface 124s. Each heater 140a may be placed near the slurry channels 142 between the bottom sections 126s. In some embodiments, a heater 140a is disposed at the inner opening 142a of each slurry channel 142. In some embodiments, the plurality of heaters 140a may be wired together to be turned on and off together. In other embodiments, the heaters 140a may be controlled independently to provide heating flexibility.

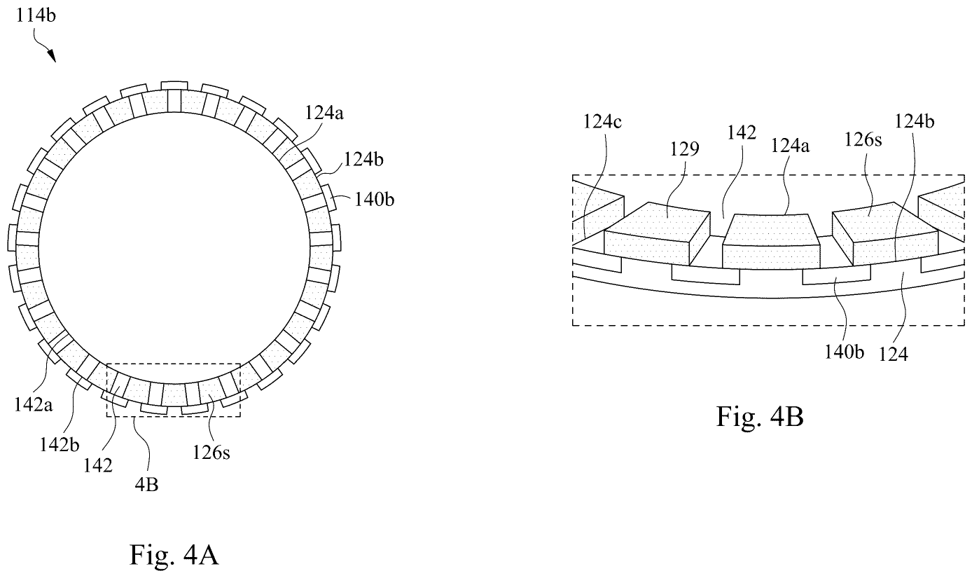

FIG. 4A is a schematic to view of a retaining ring 114b according to embodiments of the present disclosure. FIG. 4B is a partial perspective view of the retaining ring 114b in area 4B in FIG. 4A. The retaining ring 114b may be used as a retaining ring in a carrier head in a polishing station, such as the polishing station 100 of FIG. 1. The retaining ring 114b is similar to the retaining ring 114a except that the retaining ring 114b includes a plurality of heaters 140b disposed at the outer periphery 124b of the main body portion 124. In some embodiments, a heater 140b is disposed at the outer opening 142b of each slurry channel 142.

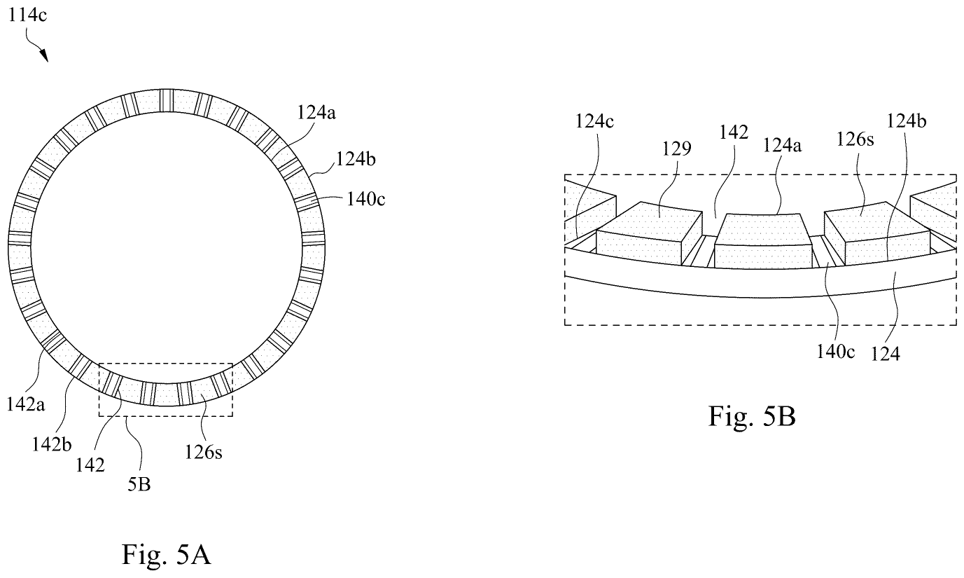

FIG. 5A is a schematic view of a retaining ring 114c according to embodiments of the present disclosure. FIG. 5B is a partial perspective view of the retaining ring 114c in area 5B in FIG. 5A. The retaining ring 114c may be used as a retaining ring in a carrier head in a polishing station, such as the polishing station 100 of FIG. 1. The retaining ring 114c is similar to the retaining rings 114a, 114b except that the retaining ring 114c includes a plurality of heaters 140c disposed at the bottom surface 124c of the main body portion 124. In some embodiments, a heater 140c is disposed along a slurry channel 142 from the inner opening 142a to the outer opening 142b.

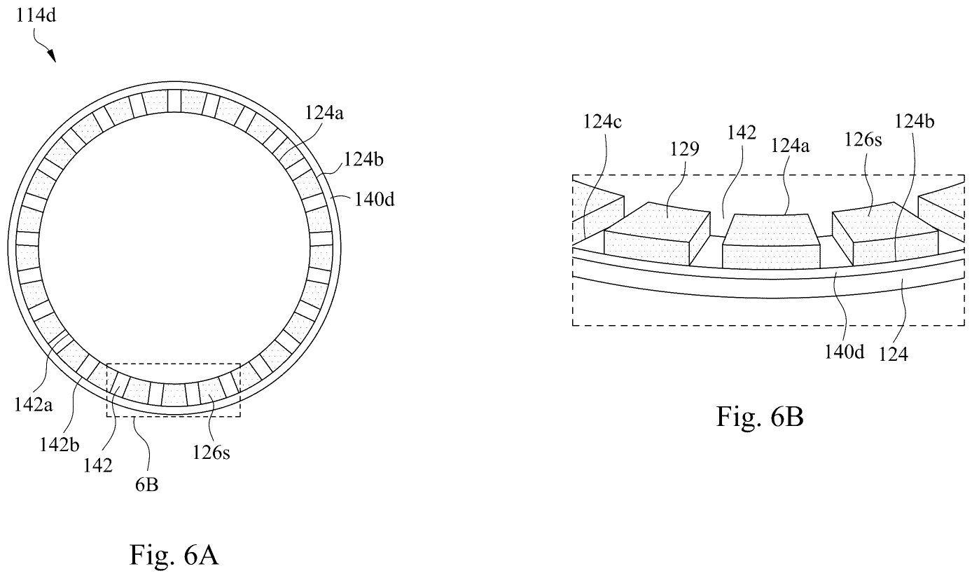

FIG. 6A is a schematic to view of a retaining ring 114d according to embodiments of the present disclosure. FIG. 6B is a partial perspective view of the retaining ring 114d in area 6B in FIG. 6A. The retaining ring 114d may be used as a retaining ring in a carrier head in a polishing station, such as the polishing station 100 of FIG. 1. The retaining ring 114d is similar to the retaining ring 114b except that the retaining ring 114d includes a single heater 140d surrounding the outer periphery 124b.

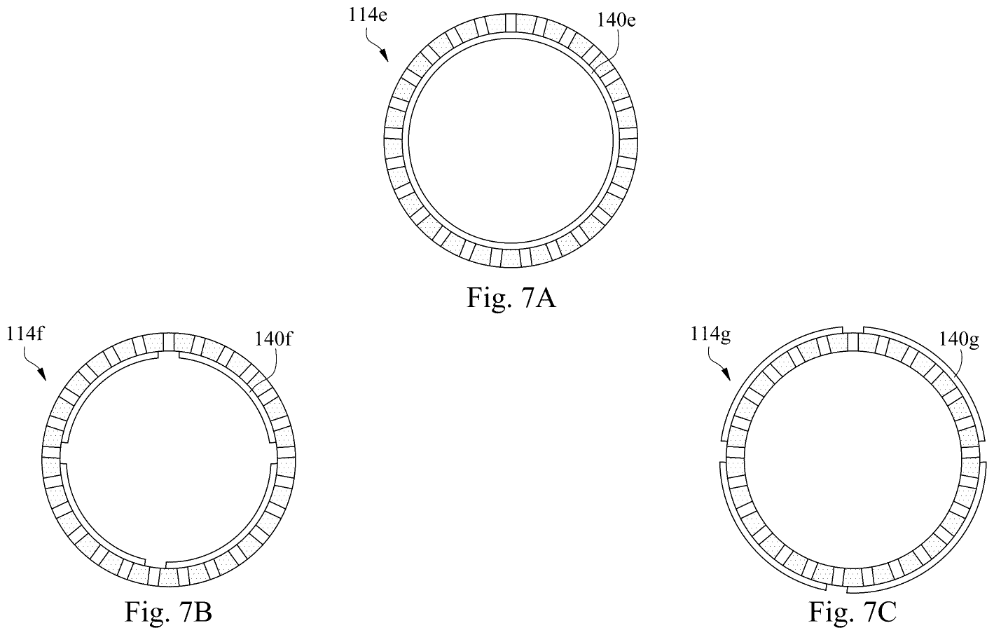

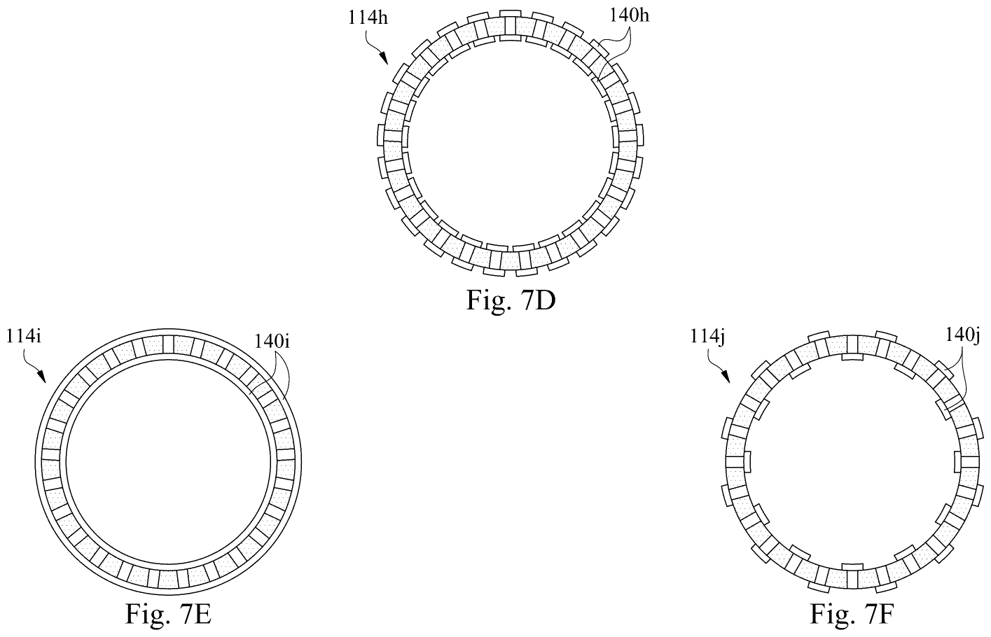

Embodiments of the present disclosure may include heated retaining rings with any suitable heater arrangements. FIGS. 7A-7F schematically illustrate several examples of retaining rings according to various embodiments. FIG. 7A schematically illustrates a retaining ring 114e having a single heater 140e disposed along the inner periphery 124a of the main body portion 124. FIG. 7B schematically illustrates a retaining ring 114f having two or more heaters 140f disposed along the inner periphery 124a of the main body portion 124. Each heater 140f may extend across several bottom sections 126s. The heater arrangement in the retaining ring 114f provides some flexibility in azimuthal heating control. FIG. 7C schematically illustrates a retaining ring 114g having two or more heaters 140g disposed along the outer periphery 124b of the main body portion 124. FIG. 7D schematically illustrates a retaining ring 114h having a plurality of heater segments 140h disposed along both the outer periphery 124b and inner periphery 124a of the main body portion 124. FIG. 7E schematically illustrates a retaining ring 114i having two heaters 140i disposed along the outer periphery 124b and inner periphery 124a of the main body portion 124 respectively. FIG. 7F schematically illustrates a retaining ring 114j having heaters 140j disposed alternatively along the outer periphery 124b and inner periphery 124a of the main body portion 124 respectively.

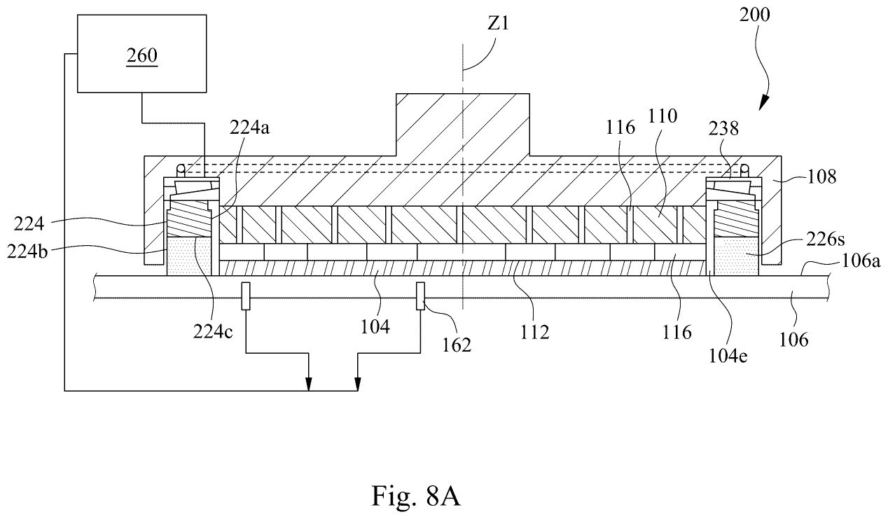

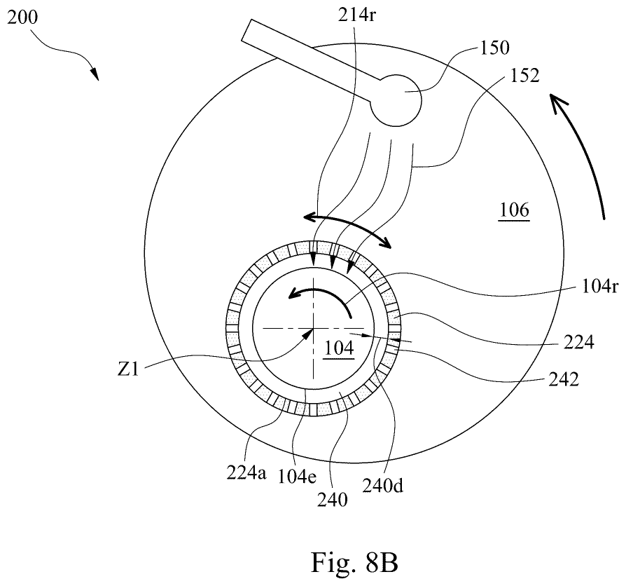

FIGS. 8A-8B schematically illustrate a carrier head 200 according to embodiments of the present disclosure. FIG. 8A is a schematic cross-sectional view of the carrier head 200. FIG. 8B is a schematic plan view of the carrier head 200 during operation. The carrier head 200 includes a rotating retaining ring 214 may be independently rotated relative to the substrate being polished.

The carrier head 200 is similar to the carrier head 102 except that the carrier head 200 includes a retainer drive assembly 238 configured to rotate the retainer ring 214 relative to the substrate 104 or the housing 108 of the carrier head 200.

As shown in FIG. 8A, the carrier head 200 includes the housing 108, the membrane support 110, the membrane 112, and the retaining ring 214. The housing 108 encloses the membrane support 110 and the substrate 104 and holds the substrate 104 against the polishing pad 106. In some embodiments, the housing 108 is operable of moving in a direction perpendicular to the polishing surface 106a of polishing pad 106 during the polishing process.

The housing 108 includes a material having sufficient mechanical strength to withstand the pressure exerted during the polishing process. In some embodiments, the retainer drive assembly 238 is attached to the housing 108, for example, attached to the housing in the retaining ring recess 117. The retaining ring 214 is connected to the retainer drive assembly 238 positioned in the retaining ring recess 117.

The retaining ring 214 may include a main body portion 224 and a bottom portion 226 connected to the main body portion 224. In some embodiments, the main body portion 224 has a continuous annular shape and is connected to the retainer drive assembly 238. The main body portion 224 includes an inner periphery 224a configured to surround the substrate 104, an outer periphery 224b, and a bottom surface 224c connecting the inner periphery 224a and the outer periphery 224b. The bottom portion 226 is attached to the bottom surface 224c of the main body portion 224. In some embodiments, the bottom portion 226 may include a plurality of segments 226s separated by a plurality of slurry channels 242 to allow the passage of slurry therethrough. Each segment 226s of the bottom portion 226 has a bottom surface 129 in contact with the polishing pad 106.

In some embodiments, the housing 108 is rotatable in a plane parallel to the polishing surface 106a of the polishing pad 106. In some embodiments, the housing 108 is pivotable about the axis Z1 perpendicular to the polishing surface 106a of the polishing pad 106.

In some embodiments, the retainer drive assembly 238 may include an activator, such as a motor, to selective rotate the retaining ring 214 relative the housing 108.

FIG. 8B schematically illustrates the position of the substrate 104 and the retaining ring 214 over the polishing pad 106. As discussed above, the inner periphery 224a of the retaining ring 214 is greater than an outer diameter 104e of the substrate 104, leaving an annular region 240 between the substrate 104 and the retaining ring 214. The annular region 240 has a width 240d along the radius of the carrier head 200. In some embodiments, the width 240d is in a range between about 1 mm and about 3 mm, for example, about 2 mm. During polishing, the slurry 152 is delivered onto the polishing pad 106 from the slurry dispenser 150. The fresh slurry 152 flows towards the substrate 104 via the slurry channels 242 under the retaining ring 214. As shown in FIG. 8B, the fresh slurry 152 enters the annular region 240 before contacting the edge of the substrate 104.

During polishing, the retainer drive assembly 238 may be activated to create a relative movement between the substrate 104 and the retaining ring 214. As shown in FIG. 8B, the substrate 104 may rotate at a rate 104r relative to the axis Z1 while the retaining ring 214 rotates at a rate 214r relative to the axis Z1. The rate 104r and the rate 214r may be in the same direction or different directions. In some embodiments, the rate 214r may be in a range between about 300 RPM and about 600 RPM, for example about 500 RPM.

The relative motion between the retaining ring 214 and the substrate 104 may create turbulent flow of the slurry 152 within the annular region 240. The relative motion may generate heat to pre-heat the flesh slurry before contacting the edge of the substrate 104. In some embodiments, the relative motion may generate heat by creating turbulent flow in the annular region 240, therefore, heating the slurry 152. Additionally, rotating the retaining ring 214 relative to the housing 108 may result in a greater relative speed between the retaining ring 214 and the polishing pad 106, thereby, creating additional heat from the friction between the retaining ring 214 and the polishing pad 106. The additional heat may raise the temperature of the retaining ring 214 and further pre-heat the slurry 152.

After pre-heating in the annular region 240 by the relative movement between the retaining ring 214 and the substrate 104, the low temperature fresh slurry would not inadvertently cool down the edge region of the substrate 104, therefore, reducing process non-uniformity across the substrate 104.

In some embodiments, the carrier head 200 further includes a controller 260. The retainer drive assembly 238 may be connected to the controller 260. The controller 260 may selectively activate the retainer drive assembly 238 to achieve desired temperature around the substrate 104. In some embodiments, the controller 260 may be connected to the one or more temperature sensors 162 in the platen 130. The controller 260 may use the sensors 162 to detect temperatures around the substrate 104, and send control signals to the retainer drive assembly 238 according to the measured temperatures.

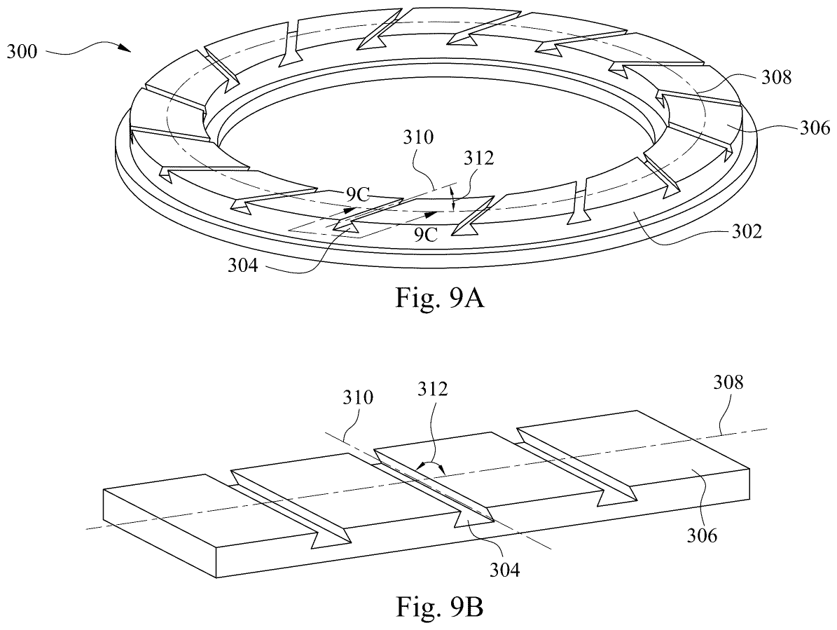

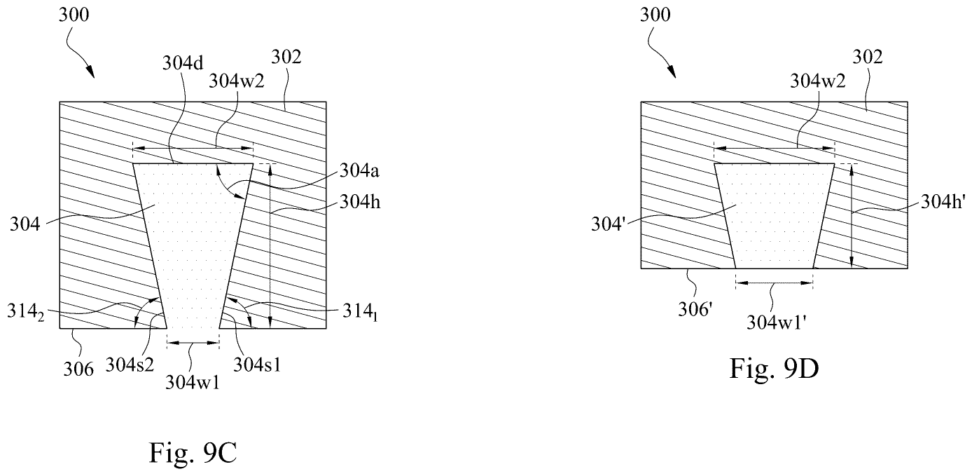

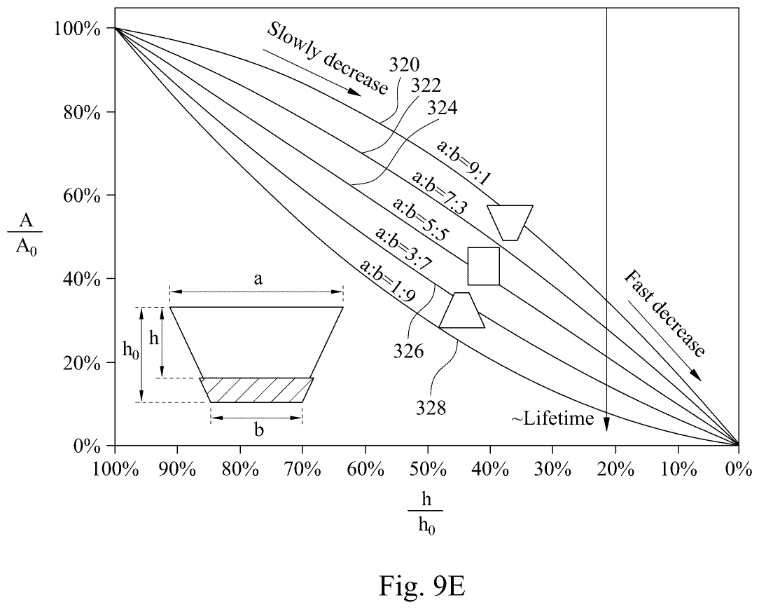

FIGS. 9A-9D schematically illustrate a retaining ring 300 according to embodiments of the present disclosure. FIG. 9A is a schematic perspective view of the retaining ring 300 according to the present disclosure. FIG. 9B is a schematic sectional of the retaining ring 300 with straight portion to show the shape of the slurry channels for there therein. FIG. 9C is a schematic partial cross section view of the retaining ring 300 along the 9C-9C direction.

The retaining ring 300 may be used in place of the retaining ring 114 and 214 above. The retaining ring 300 includes a generally annular body 302 with a hollow center for receiving a substrate therein during polishing. The annular body 302 has annular central axis 308. The annular body 302 has a bottom surface 306 which is configured to contact a polishing pad, such as the polishing pad 106 during polishing. The retaining ring 300 includes a plurality of slurry channels 304 formed through the annular body 302 at the bottom surface 306.

In some embodiments, the slurry channels 304 may be linear channels. Each slurry channel 304 has a central axis 310. In some embodiments, the slurry channels 304 may be slanted with respect to the annular central axis 308 of the annular body 302 to facility slurry flow while the retaining ring 300 rotates. The central axis 310 of the slurry channel 304 and the central axis 308 of the annular body 302 form an angle 312. In some embodiments, the angle 312 may be in a range between about 30° and about 150°.

FIG. 9C schematically illustrates a cross section of the slurry channel 304. The slurry channel 304 is formed by sidewalls 304s1, 304s2 and a top surface 304d connecting the sidewalls 304s1, 304s2. The top surface 304d is at a channel height 304h from the bottom surface 306. The slurry channel 304 has a bottom width 304w1 at the bottom surface 306, which is configured to be pressed against the polishing pad. The slurry channel 304 has a top width 304w2 near the top surface 304d. During operation, the sidewalls 304s1, 304s2, the top surface 304d, and a portion of polishing pad pressured against the bottom surface 306 define a flow area.

The slurry channels 304 provide steady and uniform slurry flow inside the carrier head on which the retaining ring 300 is attached. However, the channel height 304h decreases over time as the annular body 302 of the retaining ring 300 is being worn. The reduced channel height 304h leads to reduced slurry flow and limits the lifetime of the retaining ring 300.

The slurry channels 304 according to the present disclosure has a narrower bottom width 304w1 and a wider top width 304w2, which reduces the reduction of the flow area with the reduction of channel height 304h. In some embodiments, a ratio of the bottom width 304w1 over the top width 304w2 is in a range between about 0.1 and about 0.7. In some embodiments, at least one of the sidewalls 304s1, 304s2 of the slurry channels 304 is slanted relative to the bottom surface 306 so that the slurry channel 304 has a varied width. The sidewalls 304s1, 304s2 may form angles 3141, 3142. The angles 3141, 3142 may be in a range between about 30° and about 90°. The angles 3141, 3142 may be the same or different.

As shown in FIG. 9C, the cross section of the slurry channels 304 have a dovetail shape or tapered sidewalls. FIG. 9D is a schematic cross-sectional view of a slurry channel 304′ which results from the slurry channel 304 of FIG. 9C being worn. The channel height 304h in FIG. 9C has been reduced to a channel height 304h′ in FIG. 9D. In FIG. 9D, the channel height 304h′ has reduced to about 50% of the channel height 304h in FIG. 9C. However, the area of the slurry channel 304′ in FIG. 9D is only reduced by about 25% from the area of the slurry channel 304 in FIG. 9C.

FIG. 9E is a chart showing lifetime improvement of the retaining ring 300 according to the present disclosure. The x-axis represents a ratio of worn channel height 304h′ over the original channel height 304h. The y-axis represents a ratio of channel area A′ of the worn slurry channel 304′ over the channel area A of the slurry channel 304. Curves 320, 322, 324, 326, and 328 show the decrease of flow area A with respect to the channel height decrease. The curves 320, 322, 324, 326, and 328 correspond to slurry channels with a ratio of the top width 304w2 (a) over the bottom width 304w1 (b) of 9/1; 7/3; 5/5; 3/7; and 1/9 respectively. As shown by the curves 320, 322, 324, 326, and 328, given the same original flow areas A0, when the top width 304w2 (a) is greater than the bottom width 304w1 (b), the flow area A of the worn slurry channel 304′ is larger than when the top width 304w2 (a) is equal or less than the bottom width 304w1 (b). Additionally, when the top width 304w2 (a) is greater than the bottom width 304w1 (b), the slope of the curves is small initially and becomes steeper overtime, which is desirable.

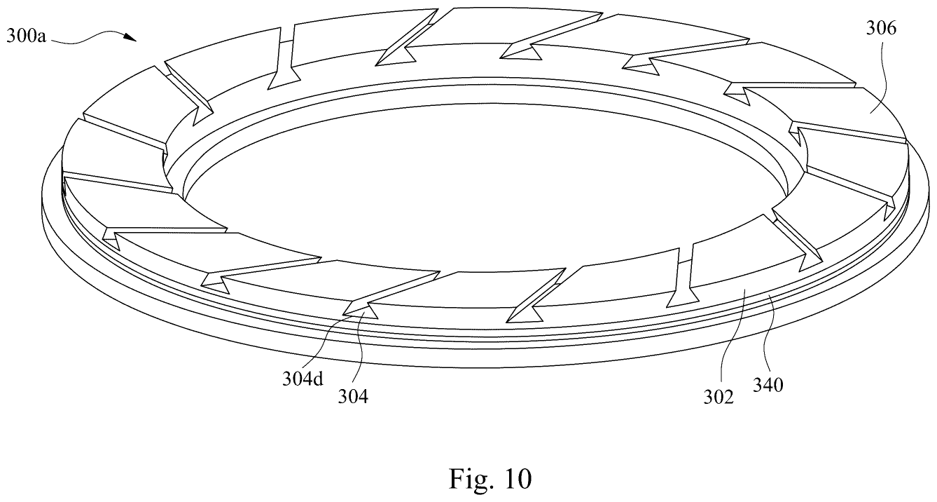

FIG. 10 schematically illustrates a retaining ring 300a according to embodiments of the present disclosure. The retaining ring 300a is similar to the retaining ring 300 except that the retaining ring 300a includes a heating element 340 disposed near the top surface 304d of the slurry channel 304. The heating element 340 is configured to pre-heat the fresh slurry before directing the fresh slurry towards the substrate disposed within the retaining ring 300a. It should be noted that the heating element 340 may be arranged differently, as shown in the retaining ring 114, 114a-114i, and 214.

Embodiments of the present disclosure provide a method and apparatus for polishing a substrate including pre-heating the polishing slurry in-situ. Particularly, the polishing slurry is preheated by a heating element attached to the retaining ring or by rotating the retaining ring relative to the substrate being processed. Pre-heating the slurry on the polishing pad improves polishing uniformity across the substrate by preventing the edge of the substrate being inadvertently cooled by the fresh slurry. Embodiments of the present disclosure further include a retaining ring with slurry channels having tapered sidewalls. The tapered sidewalls reduce the decrease of flow area as the retaining ring worn down.

Some embodiments of the present disclosure provide a retaining ring comprising a body portion; a bottom portion extending from the body portion, wherein the bottom portion comprises a plurality of segments, and a plurality of slurry channels are formed between the plurality of segments; and a heating element disposed near one or more of the plurality of slurry channels.

Some embodiments of the present disclosure provide a carrier head, comprising: a housing including a recess; a membrane support, wherein the housing encloses the membrane support; a membrane secured to the membrane support; and a retaining ring positioned in the recess of the housing, wherein the retaining ring comprises a body portion attached to the housing, wherein a plurality of slurry channels are formed on a bottom surface of the body portion, the body portion has an inner periphery and an outer periphery, and each of the plurality of slurry channels connect has an inner opening at the inner periphery of the body portion and an outer opening at the outer periphery of the body portion; and a heating element disposed near one or more of the plurality of slurry channels.

Some embodiments of the present disclosure provide a method for manufacturing integrated circuits, comprising: forming an intergrated circuit layout on a substrate; holding the substrate using a carrier head on a polishing pad, wherein a retaining ring is disposed around the substrate and a plurality of slurry channels are formed between the retaining ring and the polishing pad; dispensing a fresh slurry onto the polishing pad outside the retaining ring; and pre-heating the fresh slurry prior to flowing the fresh slurry through the plurality of slurry channels towards the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A retaining ring, comprising:
a body portion;
a bottom portion extending from the body portion, wherein the bottom portion comprises a plurality of segments, and a plurality of slurry channels are formed between the plurality of segments; and
a heating element disposed near one or more of the plurality of slurry channels.

2. The retaining ring of claim 1, wherein the body portion has an inner periphery and an outer periphery, and each of the plurality of slurry channels has an inner opening at the inner periphery of the body portion and an outer opening at the outer periphery of the body portion.

3. The retaining ring of claim 2, wherein the heating element comprises a plurality of heaters, and the plurality of heaters are disposed on the inner opening or outer opening of a corresponding plurality of slurry channels.

4. The retaining ring of claim 3, wherein each of the plurality of heaters are disposed on the inner opening of the corresponding one of the plurality of slurry channels.

5. The retaining ring of claim 3, wherein each of the plurality of heaters are disposed on the outer opening of a corresponding one of the plurality of slurry channels.

6. The retaining ring of claim 3, wherein the plurality of heaters are disposed alternatively on the outer opening and the inner opening of the plurality of slurry channels.

7. The retaining ring of claim 3, wherein the plurality of heaters are disposed on the body portion exposed in the plurality of slurry channels.

8. The retaining ring of claim 1, wherein the heating element comprises a single heater attached to the body portion.

9. A carrier head, comprising:
a housing including a recess;
a membrane support, wherein the housing encloses the membrane support;
a membrane secured to the membrane support; and
a retaining ring positioned in the recess of the housing, wherein the retaining ring comprises:
a body portion attached to the housing, wherein a plurality of slurry channels are formed on a bottom surface of the body portion, the body portion has an inner periphery and an outer periphery, and each of the plurality of slurry channels connect has an inner opening at the inner periphery of the body portion and an outer opening at the outer periphery of the body portion; and
a heating element disposed near one or more of the plurality of slurry channels.

10. The carrier head of claim 9, wherein the heating element comprises a plurality of heaters, and the plurality of heaters are disposed adjacent to the plurality of slurry channels.

11. The carrier head of claim 10, wherein the plurality of heaters are disposed on the inner periphery of the body portion.

12. The carrier head of claim 10, wherein the plurality of heaters are disposed on the outer periphery of the body portion.

13. The carrier head of claim 9, wherein the heating element comprises a single heater attached to the body portion.

14. The carrier head of claim 9, further comprising a retainer drive assembly disposed between the body portion and the housing, wherein the retainer drive assembly is operable to rotate the retaining ring relative to the housing.

15. The carrier head of claim 9, wherein the body portion has a bottom surface connecting the inner periphery and the outer periphery, each of the slurry channels has a bottom width at the bottom surface and a top width within the body portion, and the bottom width is narrower than the top width.

16. A method for manufacturing integrated circuits, comprising:
forming an intergrated circuit layout on a substrate;
holding the substrate using a carrier head on a polishing pad, wherein a retaining ring is disposed around the substrate and a plurality of slurry channels are formed between the retaining ring and the polishing pad;
dispensing a fresh slurry onto the polishing pad outside the retaining ring; and
pre-heating the fresh slurry prior to flowing the fresh slurry through the plurality of slurry channels towards the substrate.

17. The method of claim 16, wherein pre-heating the fresh slurry comprises activating a heating element attached to the retaining ring.

18. The method of claim 16, wherein pre-heating the fresh slurry comprises rotating the retaining ring relative to the substrate.

19. The method of claim 18, wherein rotating the retaining ring comprises:
rotating the substrate along a first direction; and
rotating the retaining ring along a second direction.

20. The method of claim 18, wherein rotating the retaining ring comprises:
rotating the subtrate along a first direction at a first rate; and
rotating the retaining ring along the first direction at a second rate different from the first rate.
